(19) United States
(12) Patent Application Publication
(10) Pub. No.: US 2010/0224234 A1
(43) Pub. Date: Sep. 9, 2010

(54) Solar energy system

(76) Inventor: Jay D. Fischer, Flemington, NJ (US)

Correspondence Address: ROGER M. RATHBUN, 13 MARGARITA COURT, HILTON HEAD ISLAND, SC, 29926, US

(21) Appl. No.: 12/660,646

(22) Filed: Mar. 2, 2010

Related U.S. Application Data
(60) Provisional application No. 61/209,007, filed on Mar. 3, 2009.

(51) Int. Cl. H01L 31/058; F24J 2/34; B23P 11/00

(52) U.S. Cl. 136/248; 126/617; 29/428

(57) ABSTRACT

A modular, solar energy system comprising one or more modular solar panels. The solar panels include a plurality of photovoltaic cells that are exposed to the radiant energy from the sun to create electrical power and are in heat transfer relationship with a water manifold through which water flows to remove heat from the PV cell as well as heat from the radiant energy. The heated water for the water manifold is used for heat/hot water and electricity system that can be configured using provided software and that can provide for any or all of the offerings (heat/hot water/electricity). The water manifold is constructed of a special high conductivity composite material that can be selected in accordance with the heat conductivity and customized for a particular installation. The system eliminates the use of copper and/or aluminum tubing, thereby reducing the cost and complexity of the system.

### CROSS-REFERENCE TO RELATED APPLICATIONS

The present patent application is based upon and hereby claims priority to U.S. Provisional Patent Application, Ser. No. 61/209,007 filed Mar. 3, 2009 and the specification of that Provisional Application is hereby incorporated herein in its entirety by reference.

### BACKGROUND OF THE INVENTION

The present invention is in the technical field of solar energy and, more particularly, the present invention is in the technical field of solar energy systems using solar panels for generating heat, hot water and/or electricity.

There are, at the present, solar energy systems employing solar panels that gather the radiant energy from the sun to either heat water circulating therethrough, generate electricity or both. The current solar panels, however are not truly modular, and are not easily adaptable for differing conditions, heat output, prevalent weather conditions and the like. The conventional solar energy systems are not modular to the extent that all aspects of its lifespan can benefit.

As such, the manufacturing, assembly, installation and repair of solar panels all could benefit from a totally modular system, much like the present day automobile. Additionally, when photovoltaic cells are used to generate electricity, they are, at the very best, only about 18% efficient, with the remaining energy lost as heat. The intricacies of each specialized application, that is, small townhome, large house, office, warehouse, school, etc. make the currently available systems hard to configure, price, install and maintain. And these systems are generally expensive, thus limiting widespread use and therefore restricting maximum environmentally positive impact.

One limitation is on the use of tubing to convey the heat transfer medium, typically water, through the solar panels. The present solar panels utilize copper or aluminum tubing to contain and encase the water. The thermal conductivity of copper and aluminum material is a constant and therefore the designer must live with those constants and design other parameters in order to engineer a system for a particular installation.

Accordingly, it would be advantageous to provide a different material for the construction of solar panels such that the material itself can have different, designable thermal conductivities and thereby introduce a further variable that can be taken into account in designing a more versatile system and can be designed for a specific application in a customized design applicable to the amount of heated water, electrical output or weather conditions specific to a particular installation.

### BRIEF SUMMARY OF THE INVENTION

The present invention is a solar energy system, and one major innovation is the use of photovoltaic cells in conjunction with modular composite materials (thermally conductive compounds) forming hot water passageways to capture the traditionally wasted energy (heat) during co-generation of electricity. The solar panels heat the water using material passageways formed in the composite material in place of traditional copper or aluminum tubing. Another innovation is that the entire system is designed from inception as a fully modular product easy to manufacture, easy to configure, easy to price, easy to install and easy to maintain.

The present solar energy system adds an entirely new parameter to designing and constructing solar energy systems since the systems can now also be designed by taking into account the thermal conductive of the panels themselves, that is, the panel material can be selected based on the desired conductivity of the overall panel and therefore provide an new flexible, design criteria to these solar panels.

Typically, photovoltaic cells are under 18% efficient when generating electricity and therefore the rest of the solar energy is released (wasted) as heat. Using these photovoltaic cells incorporated into the solar panel of the present invention using the molded thermally-conductive, composite material, manifolds having passageways formed therein supplement the prism/lens/mirror solar heating of the water in the panel passageways, and convert this otherwise wasted energy to use in heating the water.

The advantages of the present invention include, without limitation, that smaller, modular solar panels can be produced in such a way as to be extremely efficient (more than anything on the market) through the use of embedded PV cells alongside the solar arrays to heat the water. Additionally, the use of the particular composite material for the water conduits is more economical, efficient, lighter and recyclable than existing copper or aluminum tubing.

The present solar panels can be produced easily and inexpensively and, further are easy to assemble. The ease of manufacture and assembly of the present solar panels provides great advantages in the use of solar panels for producing heat, heated water and/or electricity. The modular design of the molded, thermally conductive composite material forming the heat exchange medium passageways makes the presence and use of copper or aluminum tubing unnecessary, thereby reducing weight, cost and maintenance.

Other features of the present solar energy system will become more apparent in light of the following detailed description of a preferred embodiment thereof and as illustrated in the accompanying drawings.

### BRIEF DESCRIPTION OF THE SEVERAL VIEWS OF THE DRAWING

FIG. 1 is a schematic view of a solar energy system constructed in accordance with the present invention;

FIG. 2 is an exploded view of a solar energy panel of the present invention,

FIG. 3 is a cross sectional side view of a panel of the present invention, and

FIG. 4 is an exploded view of a solar panel for the system of FIG. 1.

### DETAILED DESCRIPTION OF THE INVENTION

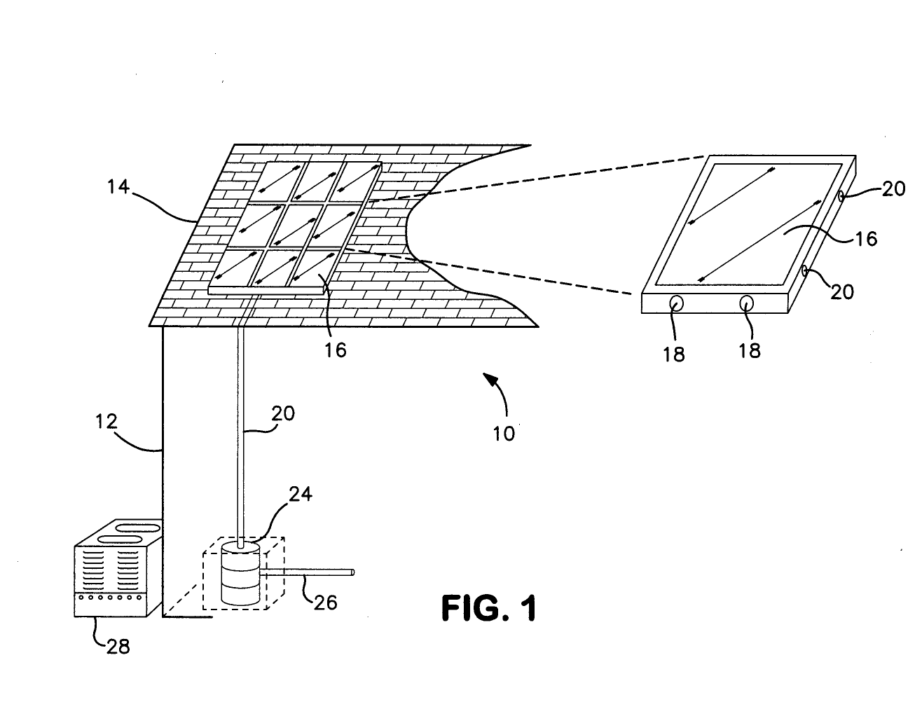

Turning first to FIG. 1, there is shown a schematic view, partially exploded, illustrating a solar energy system 10 constructed in accordance with the present invention. As can be seen, there is a building structure 12 with a roof 14 with an exposure to some form of sunlight, albeit direct or indirect. The building structure 12 can, of course, be any type of building that has a need for electricity and/or heated water. As will be seen, the present invention can be used with a structure that is devoted entirely to the production of heat, heated water and/or electricity and be a dedicated structure and not serve any other purpose such as for inhabitants.

As seen in FIG. 1, the roof 14 has a plurality of solar panels 16 arranged in columns (vertical alignment) and in rows (lateral alignment). As shown, there are nine (9) solar panels 16, however, as will become clear, the number of panels, their size and orientation may vary depending upon the particular installation, including the heat, heated water and/or electricity requirements thereof. With a modular design, a single panel can be used, or two or more, easily connected together to provide sufficient solar energy needs for the structure on which they are placed.

The solar panels 16 may be affixed to the roof 14 in a conventional manner allowing for a circulation of air between the solar panels 16 and the roof 14 or may be directly affixed flush to the roof 14. As also noted in FIG. 1, there is an exploded solar panel 16 that includes bottom ports 18 and side ports 20 and there may also be additional ports on the other side and top of the solar panel 16. The ports 18 and 20 are used to provide water communication with adjoining panels and the ports 18 and 20 are also shown as representative since there may be more or less ports that allow the communication of water circulating between adjoining solar panels 16 depending upon the particular installation. The present description herein refers to the use of water for convenience, however, it will be seen that other heat transfer mediums can circulate through the solar panels 16 including, but not limited to ethylene glycol or even air.

As is conventional, the water circulates through the solar panels 16 where it is heated by the radiant energy of the sun and the heat generated by photovoltaic cells in the solar panels themselves. The heated water can pass through a suitable pipe 22 to a reservoir 24. The reservoir 24 can also be of the modular type where additional capacity can be added or the capacity reduced by the user or the designer by stacking (with suitable connectors) and/or using multiple stacked units depending upon the configuration required. In any event, the heated water is stored and accumulated in the reservoir 24 to be used for some end purpose through a discharge pipe 26.

The solar energy system 10 can also include a heating system 28 to provide heat, when needed, so as to maintain the water in the reservoir 24 at a predetermined temperature. One type of heating system 28 can be a heat pump; however other systems can be used to maintain that predetermined temperature. The heating system 28 is the only component that will not be intrinsically modular; however several sizes/capacities (output) will be available depending on the configuration required.

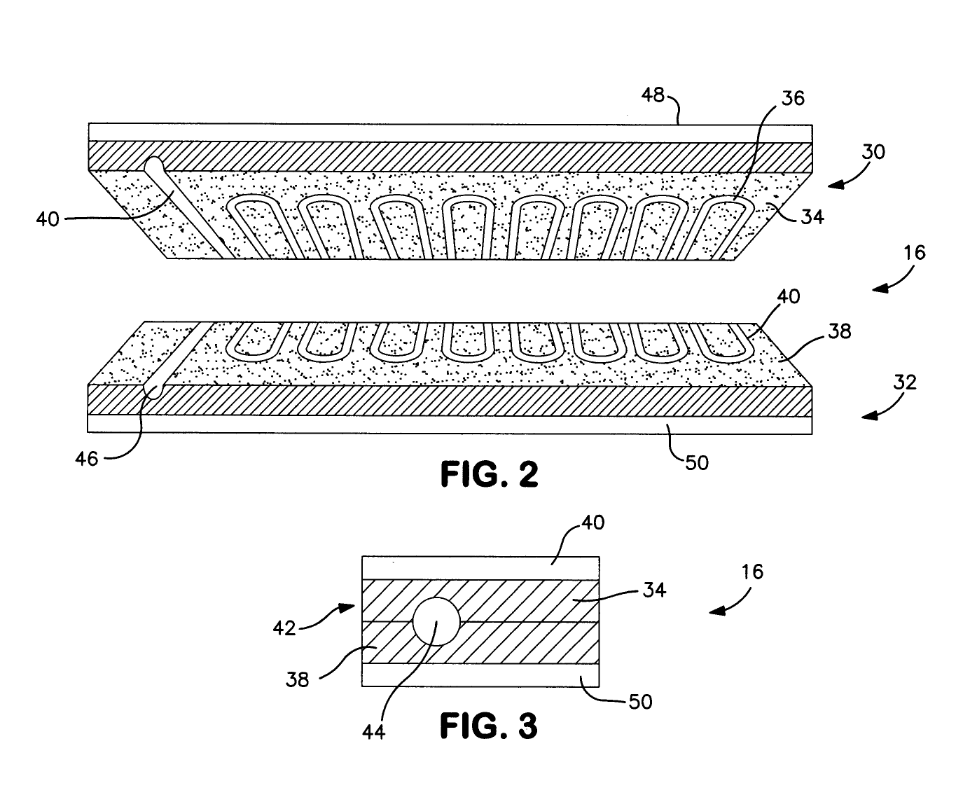

Turning now to FIGS. 2 and 3, taken along with FIG. 1, there is shown, respectively, an exploded view and a cross sectional view, of a solar panel 16 and illustrating one means of constructing an individual solar panel 16. As can be seen, the solar panel 16 of FIGS. 2 and 3 is constructed by the use of two solar panel sections, a top section 30 and a bottom section 32. The top section 30 is comprised of an upper water manifold 34 comprised of a composite material having a water passageway portion 36 formed therein and which is directly formed in the composite material making up the upper water manifold 34.

The bottom section 32 also has a lower water manifold 38 comprised of the composite material that is a mirror image of the upper water manifold 34 with a water passageway portion 40 such that when the top section 30 and the bottom section 32 are affixed together, a complete water manifold 42 is formed with a water passageway 44 formed therebetween to allow water to pass through the solar panel 16. A port 46 is thereby also formed and which can be an inlet or outlet and there is a corresponding port, not shown, that acts as the outlet or inlet for the water. Again, the number and location of the water ports in the water manifold 42 can vary according to the particular installation.

Atop of the top section 30 is a layer of photovoltaic (PV) cells 48 and which are conventional and face the sunlight to receive radiant energy to produce electricity. The PV cells 48 are affixed to the molded plastic upper water manifold 34 and an insulation material 50 is attached to the molded lower water manifold 38. With the insulation material 50, the solar panel 16 can be flush mounted to a roof and not need the space normally provided for air to pass between the solar panel 16 and a roof. The solar panel 16 can be covered with 100% with PV cells or less depending upon the end users needs thus varying the electricity in relation to the heated water.

The PV cells 32 can be conventional and obtained commercially. The water manifold 42 itself is comprised of a composite material that is selected and designed on the basis of its thermal conductivity properties. As such, the water manifold 42 allows water to pass therethrough and that water draws heat from the PV cells 48 for cooling the PV cells 48 such that the water is heated and its temperature rises as the water passes through the water manifold 42. The water is also heated by means of the radiant energy of the sun. Accordingly, the PV cells 48 are simultaneously cooled and that heat recovered as useful heat to heat the water for delivery to the reservoir 24.

With the foregoing explanation, it can be seen that while the solar panel 16 has been described as being assembled and constructed of two mating solar panel sections, the overall manifold can be made of the composite material as a single piece construction or other configuration, it being of importance that the material have high thermal conductivity and that the material of the manifold actuality form the water passageway so as to eliminate the need for tubing such as copper or aluminum tubing.

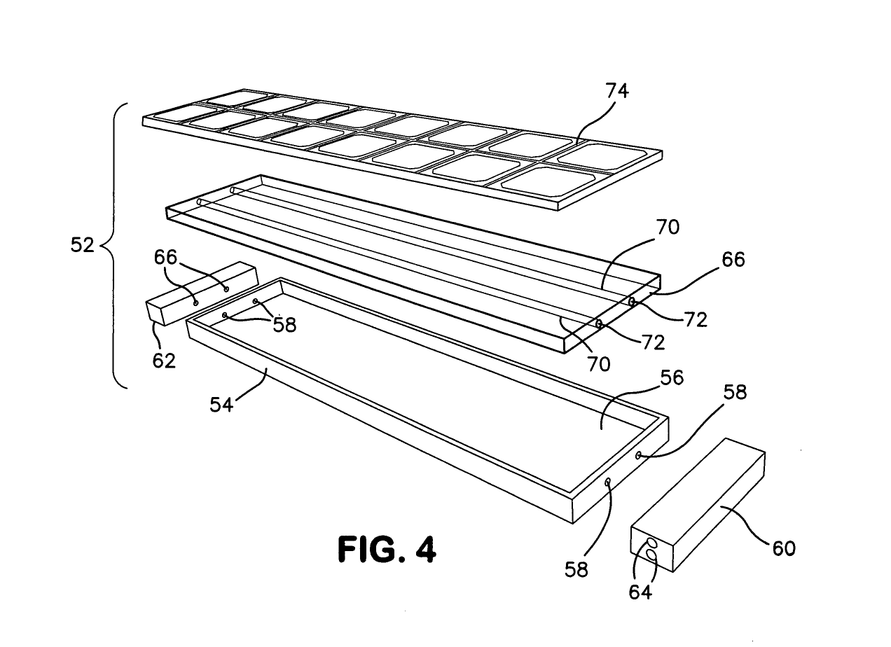

Accordingly, turning now to FIG. 4, there is shown a further exemplary embodiment of the present invention and wherein there is an exploded view of a solar panel 52 constructed in accordance with the present invention. As can be seen, there is a bottom trough 54 having a generally rectangular recessed area 56 that serves to provide a base for mounting the further components. The bottom trough also has ports 58 that pass into the recessed area 56 and the ports 58 can be inlets of outlets for the water depending upon the particular configuration and orientation of the solar panel 52. Again, as explained, while four ports 58 are shown in FIG. 4, the solar panel 52 may be designed with a larger or smaller number of ports 58 depending on the particular design of the solar panel 52 and its service.

There are also end manifolds 60, 62 that supply and receive the circulating water to the ports 58 and, as shown the end manifolds 60, 62 may have lateral openings 64 for introducing water into and from the ports 58, that is, the lateral openings 64 channel the water through passageways, now shown, ending with openings 66 that join to and communicate with the ports 58 to provide a flow path for the water. Those passageways may also pass entirely through the end manifolds 60, 62 if the solar panel 52 is interior of series of solar panels, or the passageways may dead end within the end manifolds 60, 62 if the particular solar panel is locate at the end of a series of solar panels.

Nested inside the recessed area 56 is the water manifold 66 and which has water passageways 70 that pass through the water manifold 68. The water manifold 68 as well as the passageways 70 are, again, comprised of the high conductivity molded composite material such that the passageways 70 do not include actual tubing such as copper or aluminum tubing, but instead, the passageways 70 are molded composite passageways that are molded along with the water manifold 68. Again, the molding process may be injection molding, extrusion or other manufacturing process that produces a uniform composite structure. The passageways 70 include openings 72 that allow the water to be circulated through passageways 70 to and from the end manifolds 62.

Finally, there is an array of photovoltaic (PV) cells 74 of a conventional nature that are affixed atop of the water manifold 68 and in heat transfer relationship therewith such that the circulating water through the passageways 70 remove heat from the PV cells 74 in the operation of the solar panel 52 as previously described.

The material itself for the water manifold 42 of FIGS. 2 and 3 and 68 of FIG. 4 is comprised of a high thermal conductivity composite material and that material can be supplied from various commercial sources, one of which being Applied Sciences Inc. of Cedarville, Ohio and marketed under the trademark PYROGRAF. The composition is a carbon nanofiber polymer and is described in U.S. Pat. No. 6,752,937 entitled Highly Conductive Molding Compounds Having An Increased Distribution of Large Size Graphite Particles and the disclosure of that patent is hereby incorporated herein in its entirety by reference. In the manufacture of the composite material, the thermal conductivity can be controlled so as to be a design parameter that can be selected and taken into consideration in the design of a solar energy system.

The composite material has a high thermal conductivity but can be customized to have a thermal conductivity of anywhere from 0.5 to 900 watts per meter-degrees Kelvin and above. It is preferred that the thermal conductivity be from about 50 to about 150 watts per meter-degrees Kelvin. As such the composite material can be engineered for various installations and provides yet another variable parameter in the construction of a solar energy system. The composite material can be formed as a plastic and can therefore be injection molded, extruded or otherwise made into various forms and shapes.

By the use of a totally composite manifold, the use of any tubing is eliminated and instead, the passageways for the water are formed in the composite material itself, thereby greatly reducing the costs of manufacturing the manifold and the solar panels. In addition, the solar energy system can be designed by the appropriate computer program that can take into account the thermal conductivity of the manifold and therefore add another variable to the parameters that can be selected that would not be in play with the use of copper or aluminum tubing.

All these components will be able to be computer-configured (for estimation and installation instructional purposes) based on user input (size of area to be heated, hot water usage, number of people, structure size, insulation level, geographic region, etc.) and all pertinent data also available based on this input such as configuration, size, efficiencies, estimated savings (based on user input), etc.

Further, these modular solar panels provide sufficient hot water which is maintained at a constant temperature in a reservoir of sufficient capacity. Instead of firing up alternative fuel-driven heating units when the temperature drops several degrees, the unit is designed to maintain a constant predetermined temperature, eliminating the inefficient ‘peaks and valleys’ in favor of a more efficient temperature maintenance. Additional (modular) solar panels can be added to provide for sufficient heat/hot water or co-generation of electricity, within the modular design.

Thus, the smallest common denominator, the size appropriate for a small garage, for example, will be the basic size of each modular solar panel unit, and larger sizes can be assembled by easily adding more of these modular units together.

The construction details of the invention as shown in FIGS. 1-4 are that the system configuration can be adapted to any size construction. The materials used will be appropriate for exposure (rooftop) and ideally suited for all climates and conditions. In addition, the units can be easily configured and installed into new construction as easily as retro-fitted into existing structures. All heating configurations are supported. For example, where forced hot air is already installed, a module can be installed inside the air duct to heat the air as it passes through the retrofit module. Also, the solar panels can rest flush upon a roof, as opposed to raised installation.

In broad embodiment, the present invention is a unique multi-dimensional solar panel incorporating solar panel array to heat water and PV cells to generate electricity using innovative composite conduits. Additionally the present invention is totally modular in concept for extremely easy installation and maintenance.

While the foregoing written description of the invention enables one to make and use what is considered presently to be the best, most convenient, most configurable and in all ways the most advantageous solar system thereof, those of any skill level will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

What is claimed is:

1. A modular solar panel to heat water using sunlight comprising:
a molded composite manifold having passageways formed therein for the passage of a heat conducting medium,
at least one photovoltaic cell overlying the molded plastic panel for generating electricity and for transferring heat to a heat conducting medium passing through the passageways.

2. The modular solar panel as defined in claim 1 wherein the at least one photovoltaic cell comprises a series of interconnected photovoltaic cells.

3. The modular solar panel as defined in claim 1 wherein the molded composite manifold is comprised of two mirror image panel sections, each panel section having a portion of the passageway formed therein and affixed together to align the portions of passageways to form a complete passageway.

4. The modular solar panel as defined in claim 3 wherein each panel section comprises a portion of a passageway that comprises a semi-cylindrical portion.

5. The modular solar panel as defined in claim 1 wherein the molded composite manifold is comprised of a composite material containing graphite particles and having high thermal conductivity of at least 50 watts per meter-degrees Kelvin.

6. The modular solar panel as defined in claim 5 wherein the heat conductivity varies from about 50 to about 150 watts per meter-degrees Kelvin.

7. The modular solar panel as defined in claim 1 wherein the solar panel further includes a trough having a recessed area and the molded composite manifold interfits into the recessed area.

8. The modular solar panel as defined in claim 1 wherein the molded composite manifold is injected molded.

9. The modular solar panel as defined in claim 1 wherein the molded composite manifold is extruded.

10. A method of constructing a solar panel comprising the steps of:
selecting a composite material according to the thermal conductivity of the composite material,
forming the selected composite material into a manifold having passageways comprised of the composite material formed therein,
passing a heat exchange medium through the passageways, and
attaching a plurality of photovoltaic cells to the manifold in a heat transfer relationship to transfer heat generated in the photovoltaic cells to the heat exchange medium.

11. The method of claim 10 wherein the step of forming the selected material comprises molding two sections of manifold, each having mirror images of a portion of a passageway and affixing the section together to form a completed manifold.

12. The method of claim 10 wherein the step of forming the selected material into a manifold comprises injection molding the manifold having a passageway formed therein.

13. The method of claim 10 wherein the step of forming the selected material into a manifold comprises extruding the material into a manifold having a passageway formed therein

14. The method of claim 11 wherein the step of selecting a plastic material comprises selecting a composite material comprised of highly graphitic carbon nanofibers.

15. A solar energy system for producing heated water and electrical power, the system comprising:
a plurality of solar panels comprised of a molded composite manifold having passageways formed therein for the passage of a heat conducting medium, each of said solar panels having a photovoltaic cell overlying the molded composite manifold for generating electricity and for transferring heat to a heat conducting medium passing through the passageways.

16. The solar energy system of claim 15 wherein each of the solar panels is fluidly interconnected.

17. The solar energy system of claim 15 wherein the system includes a reservoir for containing the heat conducting medium heated by the solar panels.

18. The solar energy system of claim 15 wherein the heat conducting medium is water.

19. The solar energy system of claim 17 wherein the system further includes a heating system to independently maintain the water within the reservoir at a predetermined temperature.

20. The solar energy system of claim 16 wherein molded composite manifold is comprised of a plastic material having a heat conductivity of at least 50 watts per meter-degrees Kelvin.
